(19) United States
(12) Patent Application Publication
(10) Pub. No.: US 2019/0225487 A1
(43) Pub. Date: Jul. 25, 2019

(54) Micro-electro-mechanical device with ion exchange polymer

(71) Applicant: Xergy Inc., Harrington, DE (US)

(72) Inventors: Bamdad Bahar, Georgetown, DE (US); Zhefei Li, Harrington, DE (US)

(21) Appl. No.: 15/998,668

(22) Filed: Aug. 15, 2018

Related U.S. Application Data
(60) Provisional application No. 62/545,942, filed on Aug. 15, 2017.

(51) Int. Cl. B81B 7/02; B81B 3/00

(52) U.S. Cl. CPC B81B 7/02; B81B 3/0089; B81B 3/0086; B81B 2203/04; B81B 2201/02; B81B 2203/0118; B81B 3/0067

(57) ABSTRACT

A micro-electro-mechanical device includes an ion exchange polymer coated onto a surface or within pores of a micro-electro-mechanical portion. The micro-electro-mechanical device may be an electrode, a sensor or a cantilever. The ion exchange polymer may comprise an additive, such as an inorganic particle or powder or a metal-organic framework compound. Gases may react with the ionomer and create voltage and/or current which can be measured. The incorporation of ion exchange polymer with a MEM to produce electrode can provide interesting chemical, mechanical and electrical properties, which may have promise in sensor application and some other applications. The ion exchange polymer may be either cation exchange polymer or anion exchange polymer. The ion exchange polymer can be chemically cross-linked, or reinforced by support material or additive.

### CROSS REFERENCE TO RELATED APPLICATIONS

This application claims the benefit of provisional patent application No. 62/545,942, filed on Aug. 15, 2017 and entitled Micro-Electro-Mechanical Device With Ion Exchange Polymer; the entirety of which is hereby incorporated by reference herein.

### BACKGROUND OF THE INVENTION

### Field of the Invention

The present invention relates ion exchange polymers and crosslinked ion exchange polymers or liquids combined with Micro-Electro-Mechanical (MEM) devices such as electrodes, cantilevers or sensors and applications thereof.

### Background

ion exchange polymers have attracted tremendous attention in the field of renewable energy and electrochemistry due to its unique electrical and chemical properties. ion exchange polymers are formed by a polymeric backbone functionalized with side chains consisting of ionic groups and counter ions, which sustain the ionic conductivity. There are two types of ion exchange polymers, cation exchange polymer and anion exchange polymer. Cation exchange polymer consists of polymer backbone functionalized with anionic side chain with counter cations, while anion exchange polymer is made up of polymer backbone functionalized with cationic side chain with counter anions. Typical anionic groups in cation exchange polymer may be carboxylic and sulfonic, and counter cations can be H⁺, Na⁺, K⁺, etc. Cationic groups in cation exchange polymer are typically quaternary ammonium, pyridinium, piperidinium, etc, and counter cations can be OH⁻, HCO₃⁻, CO₃²⁻, etc. on exchange polymers are often referred to as ionomer.

Micro-electro-mechanical systems (MEMS) are the miniature mechanical and electrical components that are produced by microfabrication. The size of MEMS devices can vary between hundreds of nanometer to hundreds of micron. Due to the advantage of reduced weight and volume in MEMS technology, it has been widely used to fabricate electronic products in semiconductor industry, from microchips to display technologies to sensor systems. Particularly, miniature sensors increase flexibility in small assembly machines and can provide high precision and ensure the necessary reliability.

### SUMMARY OF THE INVENTION

The invention is directed to ion exchange polymers and crosslinked ion exchange polymers or liquids combined with Micro-Electro-Mechanical, MEM, devices, such as electrodes, cantilevers or sensors and applications thereof.

This application incorporates by reference the following: U.S. provisional patent application No. 62/171,331, filed on Jun. 5, 2015 and entitled Electrochemical Compressor Utilizing a Preheater; U.S. patent application Ser. No. 14/859,267, filed on Sep. 19, 2015, entitled Electrochemical Compressor Based Heating Element and Hybrid Hot Water Heater Employing Same; U.S. patent application Ser. No. 13/899,909 filed on May 22, 2013, entitled Electrochemical Compressor Based Heating Element And Hybrid Hot Water Heater Employing Same; U.S. provisional patent application No. 61/688,785 filed on May 22, 2012 and entitled Electrochemical Compressor Based Heat Pump For a Hybrid Hot Water Heater; U.S. patent application Ser. No. 14/303,335, filed on Jun. 12, 2014, entitled Electrochemical Compressor and Refrigeration System; U.S. patent application Ser. No. 12/626,416, filed on Nov. 25, 2009, entitled Electrochemical Compressor and Refrigeration System now U.S. Pat. No. 8,769,972; and U.S. provisional patent application No. 61/200,714, filed on Dec. 2, 2008 and entitled Electrochemical Compressor and Heat Pump System; the entirety of each related application is hereby incorporated by reference.

In an exemplary embodiment, the invention provides for the incorporation of the ion exchange polymer in situ, to retain the ion exchange polymer in place on or in a porous MEM portion, such as an electrode or sensor component, such as a cantilever. Incorporation can be accomplished by various coating technologies, such as dip coating, drop casting, screen printing, ultrasonic spraying, etc. Additional post-treatment process can be incorporated, like crosslinking by heat, UV or IR; or chemically by adding agents in the precursor solution. Properties of the ion exchange polymer can be altered by reinforcement with different additives, such as inorganic filler including, but not limited to, silica, alumina, zirconia, titania, cerium oxide, boron oxide, zirconium phosphate, etc. In addition, additives such as metal hydride or metal organic framework material may be incorporated into the ionomer or the ionomer incorporated therein for greater and more accurate sensitivity. Any of the additives described herein may be incorporated in a concentration by weight of the ionomer and additive composition of about 0.5% or more, about 1% or more, about 3% or more, about 5% or more and any range between and including the concentrations provided. Additives may be incorporated homogenously throughout the ionomer or may be coated on one side or in a gradient from one surface to the opposing surface. The additives may change the ion conducting properties and stiffness of the ionomer/additive composition and therefore specific coating strategies may be employed to enhance the sensitivity of the MEM device. In one embodiment a first additive is configured on or proximal to a first surface and a different additive is configured on or proximal to the opposing surface. The additives may be small particles or powder additives and may have an average particle size of about a few microns or less, or less than a micron, such as about 0.1 micron to 1 micron, or 0.5 micron or more, and any range between and including the average particle sizes listed.

For example, an ionomer may be incorporated within a nanoporous MEMS cantilever array which may be 500 μm in length, or 50-100 μm in length, and 1 μm in thickness for example. The ionomer may be a cation exchange polymer or cationic ionomer, a proton-conducting polymer, such as a sulfonated tetrafluoroethylene based fluoropolymer-copolymer, available from Dupont, under the tradename NAFION; referred to as a perfluorinated sulfonic acid polymer, herein. Ionomer may be first dispersed in a solvent mixture of alcohol and water. Then the ionomer solution can coated onto the MEMS cantilever array by ultrasonic spray, generated by an ultrasonic nozzle and a peristaltic pump. The thickness and mass loading of ionomer coating can be varied by changing the pumping speed, solution concentration and spraying time. Other coating technologies, such as dip coating, drop casting, screen printing may also be used. An additive, such silica nanoparticles may be included up to several weight percent of to enhance the mechanical property of ionomer thin film. The resulting material exhibits excellent cation exchange capacity.

Another example is the incorporation of an anion exchange polymer, quaternary ammonium-tethered poly(biphenyl alkylene), within a nanoporous MEMS electrode. This anion exchange polymer may be crosslinked chemically by diamine to enhance the mechanical property and stability. The resulting material exhibits excellent anion exchange capacity. An anion exchange polymer may be cross linked as described in U.S. patent application Ser. No. 15/627,577 to Bamdad Bahar et al., or U.S. provisional patent application 62/594,076, to Bamdad Bahar, et al; the entirety of each are hereby incorporated by reference.

The incorporation of ion exchange polymers within MEMS electrode can provide interesting chemical, mechanical and electrical properties. Thermal and mechanical stability are improved and also the conductivity. The ion exchange groups in these polymers can react with different species, thus, they may have promise in sensor application and some other applications.

In addition, ionic liquids may be incorporated into MEMS as they are functional and can provide transport of ionic species within a MEMS device. The MEMS based sensor's chemical response is a function of the ionic liquid engaged and its rate of adsorption and desorption.

Gas phase adsorption is a complex, physical-chemical process in which gas molecules become attached to the surface of a materials. The amount of each gas that can become adsorbed to that surface is dictated by the thermodynamic equilibria that exist between that material, the gas molecules attached to the surface of that material, and the amount of each gas species in the gas phase. Therefore, it is theoretically possible to calculate the concentration of those gases in the local atmosphere based on the total amount of each gas adsorbed onto the material surf ace. In addition, the thermodynamic models of adsorption are well suited for both low and high-pressure systems

Adsorption, as opposed to absorption, takes place on the surface of the material. This interaction can occur chemically through covalent bonding, or physically through Van der Waals forces. Typical adsorbers are solid materials with large surface areas, such as zeolites, activated carbons, metal oxides, Metal-organic-frameworks (MOFs), silica gels, and ionic media. In this sensor application, we are focusing only on media with a fast rate of adsorption, and desorption, that can be achieved with very thin, nano-meter scale, and high surface area films. Prior work conducted by the team, has determined that certain ionic liquids (ILs) are ideal for sensors and exhibit a high rate of adsorption and desorption (i.e. regeneration) as high surface area films; and other materials such as zeolites, carbons, silica and metal structures respond too slowly and require energy for regeneration. In addition, certain ionic liquids exhibit high selectivity to CO2, and are not affected by other gases or contaminants.

Ionic liquids are commonly defined as materials that are comprised of large organic cations and organic/inorganic anions, which demonstrate good chemical. To date a wide range of ionic liquids has been synthesised through different combinations of anions and cations. It has been stated that the theoretical number of potential ionic liquids is to the order of 1018. Ionic liquids possess several unique and diverse characteristics such as high thermal and chemical stability, low vapour pressure, large chemical window, tunable/designer nature, and excellent solvent properties for a range of polar and nonpolar compounds (useful for casting or manufacturing systems). Ionic liquids over the past decade has spanned into many sectors of industry.

More specifically, ionic liquids have demonstrated many advantages for CO2 adsorption comparted to other media: (i) their adsorption process is less energy intensive, and thus fast regeneration is feasible due their inherent physical absorption mechanisms; (ii) further efficiency is attained by their low vapour pressure, which allows them to be regenerated and reused with no appreciable losses into the gas stream; (iii) ionic liquids have a high thermal and chemical stability; typically they degrade at temperatures >300° C. avoiding their reaction with impurities and causing corrosion to MEMS substrate, (iv) ionic liquids are tunable and the designer nature of ionic liquids offers many options concerning the physicochemical properties (viscosities and densities, heat capacities, decomposition, surface tension, toxicity and health issues, and corrosion) in the sense that the anions and cations can be manipulated to create an IL for the specific CO2 adsorption task.

This designer aspect can also be applied to the anion or cation in the sense that various chemical functionalities and structures can be attached, allowing properties such as adsorption and viscosity to be controlled. These are commonly referred to as task-specific ionic liquids (TSILs).

In order to create an optimal process for CO2 adsorption in ionic liquids, assessment of the essential building blocks, that is, cation/anion combinations, will be modeled and investigated. Synthesising ionic liquids that encompass CO2-philic groups on the anion such as carbonyls or fluorines has proven to increase CO2 adsorption. Also widely researched are task-specific ionic liquids with appended amine groups.

An ionic liquid may be imbibed to form a thin, and high surface area ionic liquid into or on a matrix of a porous, such as nanopours, MEMS substrate, and subsequently chemically cross-linked to lock the ionic liquids on or into the substrate.

Exemplary ionic liquids include, but are not limited to, carbamate ionic liquids which can be formed from the reaction between dipropylamine and CO2, along with imidazolium, pyridinium, pyrrolidinium.

Any number of compounds may interact with the ion exchange polymer including, but not limited to, CO2, volatile air components and pollutants such as formaldehyde, NOx, SOx, ammonia, VOC, ozone and the like.

This technology to integrate Ionic media with MEMS systems is transformational and disruptive and has applicability to a wide range of applicability for detection of gases and other important spheres. It will also enable the establishment of a whole new technology platform gas detection. By developing a sensor capable of detecting the mass or molar concentration of a mixture of adsorbed gases, as well as determining the total atmospheric pressure, it will be conceivable to then model the composition of that air sample to estimate the concentration of CO₂, CH₄, SO₂, H₂O or any other gas species of interest that may be present in the air. These estimations can be accomplished by developing software modules based on state-of-the-art solver routines to solve the non-linear thermodynamics that governs the theory of mixed gas adsorption. That software can then be coupled with the sensors to create real time readouts of the gas composition in the air.

An ionomer is a polymer that comprises repeat units of both electrically neutral repeating units and a fraction of ionized units (usually no more than 15 mole percent) covalently bonded to the polymer backbone as pendant group moieties.

A micro-electro-mechanical, MEM, device or system as described herein may incorporate a metal-organic compound or microporous metal-organic compound as described in U.S. Pat. No. 8,466,285, to Stuart Lloyd James, et al; the entirety of which is hereby incorporated by reference herein. An ionomer, or ion exchange polymer, may be used as an adhesive or binder for the MOF material, such as particles or powder. An exemplary metal-organic compound or MOF material may be otherwise coated onto the MEM portion or device without any ionomer such as with an alternative adhesive or by impregnation into pores of the MEM portion.

An exemplary micro-electro-mechanical device may comprise a support material for the ion exchange polymer. The support material may be a thin porous layer of material that allows the ion exchange material to be at least partially imbibed into the pores therein. A support material may reinforce the ionomer mechanically and reduce expansion and contraction of the ionomer, such as from the absorption of water. An exemplary support material is a fluoropolymer support material, such as a porous fluoropolymer material. An exemplary porous fluoropolymer material is an expanded polytetrafluoroethylene (ePTFE), such as an ePTFE membrane, having nodes interconnected by fibrils and a plurality of pores or porosity to receive the ionomer. An exemplary expanded polytetrafluoroethylene may be very thin, such as less than about 5 microns, or less than 2 microns, or less than 1 micron, such as about 0.5 microns or less, about 0.1 micron or less about, 0.01 micron or less, about 0.001 micron to about 0.5 micron, and any range between and including the thickness values provided.

The summary of the invention is provided as a general introduction to some of the embodiments of the invention and is not intended to be limiting. Additional example embodiments including variations and alternative configurations of the invention are provided herein.

### BRIEF DESCRIPTION OF SEVERAL VIEWS OF THE DRAWINGS

The accompanying drawings are included to provide a further understanding of the invention and are incorporated in and constitute a part of this specification, illustrate embodiments of the invention, and together with the description serve to explain the principles of the invention.

FIG. 1 shows an exemplary embodiment of a MEM device comprising an ion exchange polymer coated on the surface.

FIG. 2 shows an exemplary embodiment of a MEM device comprising an ion exchange polymer coated in the porous material of the MEM device and on the surface.

FIG. 3 shows an exemplary embodiment of a MEM device comprising an ion exchange polymer coated onto a MEM device.

Corresponding reference characters indicate corresponding parts throughout the several views of the figures. The figures represent an illustration of some of the embodiments of the present invention and are not to be construed as limiting the scope of the invention in any manner. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

### DETAILED DESCRIPTION OF THE ILLUSTRATED EMBODIMENTS

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Certain exemplary embodiments of the present invention are described herein and are illustrated in the accompanying figures. The embodiments described are only for purposes of illustrating the present invention and should not be interpreted as limiting the scope of the invention. Other embodiments of the invention, and certain modifications, combinations and improvements of the described embodiments, will occur to those skilled in the art and all such alternate embodiments, combinations, modifications, improvements are within the scope of the present invention.

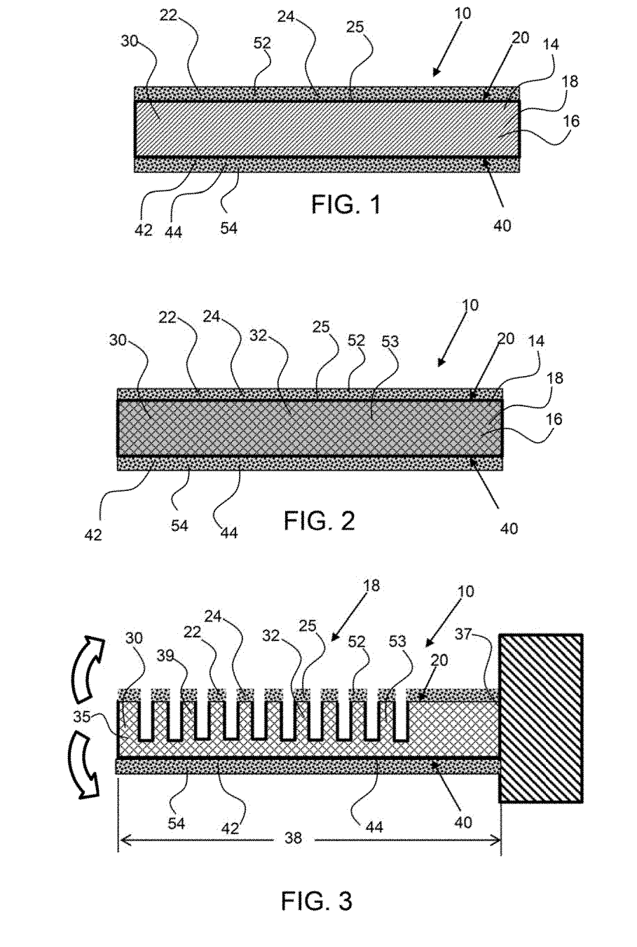

As shown in FIG. 1, an exemplary MEM device 10 comprises an ion exchange polymer coated on the surfaces of a MEM portion 30. A first ion exchange polymer 22 is coated onto the first surface 20 and a second ion exchange polymer 42 is coated on a second surface. The first and second ion exchange polymers may be the same or different types of ion exchange polymer. Note that the ion exchange polymer may be coated onto only a single side of the MEM portion, such as on the first side only. An additive 52 may be configured in the ionomer, or ion exchange polymer 22 on the first side and a second additive 54 may be configured in the ionomer on the second side, or the second ion exchange polymer 42. The first and second additives may be the same or different materials and may include, but are not limited to including, silica, alumina, zirconia, titania, cerium oxide, boron oxide, zirconium phosphate, metal hydride or metal organic framework material.

As shown in FIG. 2, an exemplary MEM device 10 comprises an ion exchange polymer coated on the surfaces of a MEM portion 30 as well as in the pores 32 or porous portion of the MEM portion. A MEM portion may comprise pores proximal the first surface 20 or second surface 40 or through the thickness, as shown. A first ion exchange polymer 22 may be coated onto the first surface 20 and into pores of extending from the first surface and a second v 42 may be coated on a second surface and into the pores extending from the second surface. The first and second ion exchange polymers may be the same or different types of ion exchange polymer, such as different ionomers, on an anion exchange polymer on a first side and a cation exchange polymer on a second side. Note that the ion exchange polymer may be coated onto only a single side of the MEM portion, such as on the first side and into any pores extending from the first side. A first additive 52 may be configured in the ionomer, or ion exchange polymer 22 on the first side and a second additive 54 may be configured in the ionomer on the second side, or the second ion exchange polymer 42. A third additive 53 may be incorporated into the ionomer that is within the pores of the MEM portion. The first, second and third additives may be the same or different materials and may include, but is not limited to including, silica, alumina, zirconia, titania, cerium oxide, boron oxide, zirconium phosphate, metal hydride or metal organic framework material.

The MEM portion shown in FIGS. 1 and 2 may be a cantilever 18 portion that is deflects when an ionic species is absorbed or adsorbed by the ion exchange polymer. This deflection or movement of the cantilevered MEM portion may be detected through any number of ways to provide a sensor for the species absorbed or adsorbed by the ion exchange polymer. For example, carbon dioxide may be absorbed into the depth of the Ion exchange polymer and cause the cantilever to deflect. The specific ion exchange polymer may be chosen to cause a target gas or compound to absorb into the ion exchange polymer or adsorb onto the surface of the ion exchange polymer.

The MEM devices shown in FIGS. 1 and 2 may be a sensor 14, or an electrode 16. Leads may be coupled to the MEM device to measure voltage and or current or some other sensor or monitoring component may be coupled with the MEM device to measure electrical properties and/or mechanical changes, such as deflection, strain and the like.

As shown in FIG. 3, a MEM device 10 is a cantilever 18 having a fixed end 37 and a cantilevered end 35. The MEM device has a plurality of teeth 39 that extend to a first surface 20. The tips of the teeth comprise an ion exchange polymer 22 which may have an additive 52. The second surface 40 of the MEM device may have an ion exchange polymer 42 having a second side additive 54. The type of ionomer and additive may be selected to achieve a high deflection of the cantilevered MEM when exposed to various gases, for example. Furthermore, Metal-organic-frameworks (MOFs), may be coated onto or into a portion of the MEM device along with an ionomer as a binder or directly onto or into the MEM device. The MEM portion has a length from the fixed end to the extended end which may be from a hundred or more nanometers to about 990 microns.

As shown in FIGS. 1 to 3, a MEM device may comprise a support material 24, 44 on the first or second surface, respectively. The support material may be porous having pores 25 for receiving ionomer and/or additives therein. As described herein, an exemplary support material may be a very thin porous membrane, such as an ePTFE membrane having a thickness of no more than 1 micron. The ionomer and/or MOF material may be coated onto or into the support material. The additives may be configured on or within the pores of the support material. In an exemplary embodiment, an ionomer with additives is coated onto a support material, such as an ePTFE membrane, and the ionomer wicks into the pores but the additives are retained on the surface of the ePTFE membrane as the particle size is larger than the pore or pore openings of the ePTFE membrane. This produces a high concentration of additives on the surface of the support material and a gradient through the thickness of the composite coated MEM portion.

It will be apparent to those skilled in the art that various modifications, combinations and variations can be made in the present invention without departing from the spirit or scope of the invention. Specific embodiments, features and elements described herein may be modified, and/or combined in any suitable manner. Thus, it is intended that the present invention cover the modifications, combinations and variations of this invention provided they come within the scope of the appended claims and their equivalents.

What is claimed is:

1. A micro-electro-mechanical device comprising:
a) micro-electro-mechanical portion;
b) an ion exchange polymer coated onto the micro-electro-mechanical portion;
wherein the MEMS portion has a length of between a hundred nanometers to about 990 microns.

2. The micro-electro-mechanical device of claim 1, wherein the ion exchange polymer is a cation exchange polymer.

3. The micro-electro-mechanical device of claim 2, wherein the ion exchange polymer is a perfluorinated sulfonic acid polymer.

4. The micro-electro-mechanical device of claim 1, wherein the ion exchange polymer is an anion exchange polymer.

5. The micro-electro-mechanical device of claim 4, wherein the anion exchange polymer is crosslinked.

6. The micro-electro-mechanical device of claim 4, wherein the ion exchange polymer is a quaternary ammonium-tethered poly(biphenyl alkylene).

7. The micro-electro-mechanical v of claim 1, further comprising an additive within the ion exchange polymer.

8. The micro-electro-mechanical device of claim 1, wherein the additive is an inorganic filler.

9. The micro-electro-mechanical device of claim 8, wherein the inorganic filler is selected from the group consisting of: silica, alumina, zirconia, titania, cerium oxide, boron oxide, and zirconium phosphate.

10. The micro-electro-mechanical v of claim 7, wherein the additive is a metal-organic compound (MOF).

11. The micro-electro-mechanical device of claim 1, wherein the ion exchange polymer is reinforced by support material.

12. The micro-electro-mechanical device of claim 1, wherein the support material is a porous support material and wherein at least a portion of the ion exchange polymer is configured within the support material.

13. The micro-electro-mechanical device of claim 12, wherein the support material comprises an expanded polytetrafluoroethylene membrane.

14. The micro-electro-mechanical device of claim 13, wherein the expanded polytetrafluoroethylene membrane has a thickness of no more than 1 micron.

15. The micro-electro-mechanical device of claim 1, wherein the micro-electro-mechanical device forms a portion of a sensor.

16. The micro-electro-mechanical device of claim 1, wherein the micro-electro-mechanical device is an electrode.

17. The micro-electro-mechanical device of claim 1, wherein the micro-electro-mechanical device is a cantilever.

18. A micro-electro-mechanical device comprising:
a) micro-electro-mechanical portion;
b) a metal-organic compound coated onto the micro-electro-mechanical portion.

19. The micro-electro-mechanical device of claim 18, further comprising an ionomer coupled between the micro-electro-mechanical portion and the metal-organic compound.

20. The micro-electro-mechanical device of claim 18, wherein the micro-electro-mechanical device is a cantilever.
